(19) United States
(12) Patent Application Publication
(10) Pub. No.: US 2024/0407200 A1
(43) Pub. Date: Dec. 5, 2024

(54) DISPLAY DEVICE AND MANUFACTURING METHOD OF DISPLAY DEVICE

(71) Applicant: Japan Display Inc., Tokyo (JP)

(72) Inventor: Arichika ISHIDA, Tokyo (JP)

(73) Assignee: Japan Display Inc., Tokyo (JP)

(21) Appl. No.: 18/731,921

(22) Filed: Jun. 3, 2024

(30) Foreign Application Priority Data
Jun. 5, 2023 (JP) 2023-092277

(51) Int. Cl. H10K 59/122; H10K 59/12

(52) U.S. Cl. CPC H10K 59/122; H10K 59/1201

(57) ABSTRACT

According to one embodiment, a display device includes an organic insulating layer, a lower electrode provided on the organic insulating layer, a planarization layer which is provided on the organic insulating layer and is in contact with a side surface of the lower electrode, an inorganic insulating layer which covers the planarization layer and covers a peripheral portion of the lower electrode, a partition having a lower portion and an upper portion, an organic layer surrounded by the partition, provided on the lower electrode and including a light emitting layer, and an upper electrode which is surrounded by the partition, is provided on the organic layer and is in contact with the lower portion of the partition.

### CROSS-REFERENCE TO RELATED APPLICATION

This application is based upon and claims the benefit of priority from Japanese Patent Application No. 2023-092277, filed Jun. 5, 2023, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In display elements, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a plan view showing an example of a planarization layer 13.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining a method for forming the planarization layer 13.

FIG. 16 is a diagram for explaining another method for forming the planarization layer 13.

FIG. 17 is a diagram for explaining another method for forming the planarization layer 13.

FIG. 18 is a diagram showing an example of the cross-sectional shape of the planarization layer 13.

FIG. 19 is a diagram showing another example of the cross-sectional shape of the planarization layer 13.

FIG. 20 is a diagram for explaining the process of selectively forming the planarization layer 13 in a display area DA.

### DETAILED DESCRIPTION

Embodiments described herein aim to provide a display device and a manufacturing method of a display device such that the reduction in reliability can be prevented.

In general, according to one embodiment, a display device comprises a substrate, an organic insulating layer provided above the substrate, a lower electrode provided on the organic insulating layer, a planarization layer which is provided on the organic insulating layer and is in contact with a side surface of the lower electrode, an inorganic insulating layer which covers the planarization layer and covers a peripheral portion of the lower electrode, a partition having a lower portion which is provided on the inorganic insulating layer and is formed of a conductive material and an upper portion which is provided on the lower portion and protrudes from a side surface of the lower portion, an organic layer surrounded by the partition, provided on the lower electrode and including a light emitting layer, and an upper electrode which is surrounded by the partition, is provided on the organic layer and is in contact with the lower portion of the partition.

According to another embodiment, a manufacturing method of a display device comprises forming an organic insulating layer above a substrate, forming a lower electrode on the organic insulating layer, applying a positive photosensitive resin which covers the organic insulating layer and the lower electrode, forming a planarization layer which is in contact with a side surface of the lower electrode by patterning the photosensitive resin, forming an inorganic insulating layer which covers the planarization layer and covers a peripheral portion of the lower electrode, forming a partition having a lower portion which is located on the inorganic insulating layer and is formed of a conductive material and an upper portion which is located on the lower portion and protrudes from a side surface of the lower portion, forming an organic layer located on the lower electrode and including a light emitting layer by vapor deposition using the partition as a mask, and forming an upper electrode which is located on the organic layer and is in contact with the lower portion of the partition by vapor deposition using the partition as a mask.

The embodiments can provide a display device and a manufacturing method of a display device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the embodiment is an organic electroluminescent display device comprising an organic light emitting diode (OLED) as a display element, and could be mounted on a television, a personal computer, a vehicle-mounted device, a tablet, a smartphone, a mobile phone, etc.

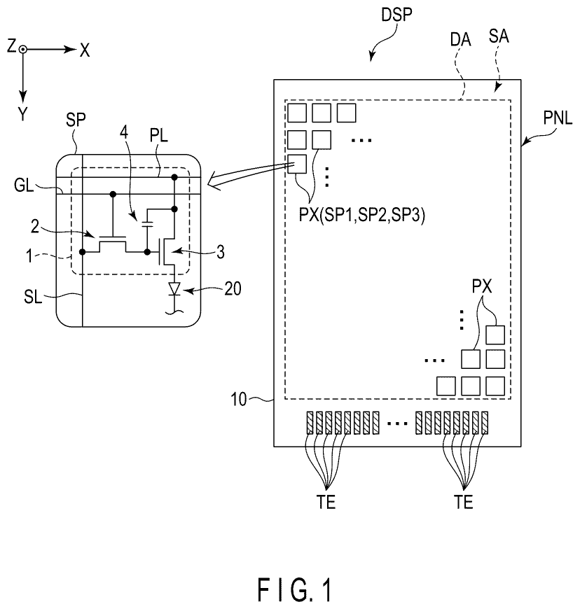

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4 etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Terminals TE for connecting an IC chip and a flexible printed circuit are provided in the surrounding area SA.

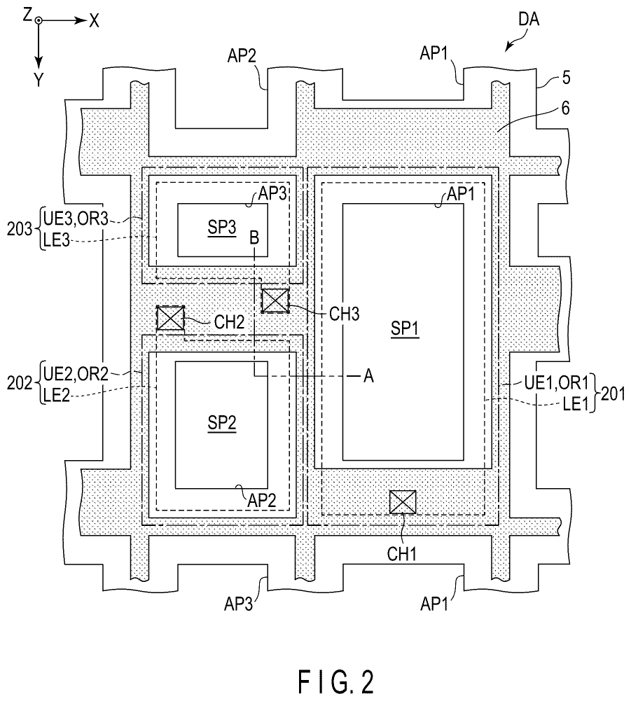

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 in plan view. The peripheral portion of each of the organic layer OR and the upper electrode UE1 overlaps the inorganic insulating layer 5 in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

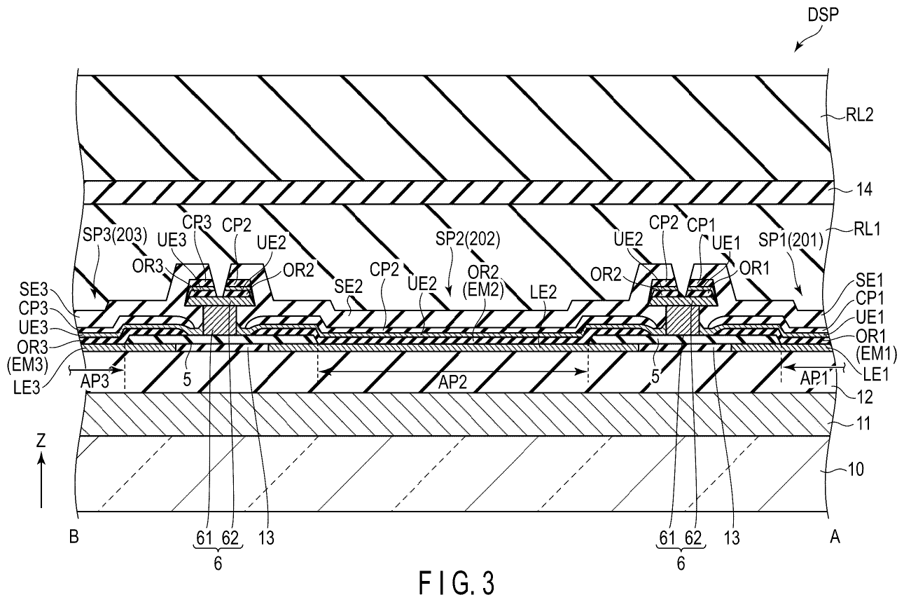

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

A planarization layer 13 is provided on the insulating layer 12. The upper surface of each of the lower electrodes LE1, LE2 and LE3 is exposed from the planarization layer 13. The planarization layer 13 is in contact with the side surfaces of each of the lower electrodes LE1, LE2 and LE3. The planarization layer 13 has the same thickness as each of the lower electrodes LE1, LE2 and LE3. For example, the thickness of the planarization layer 13 is 50 to 100 nm.

The inorganic insulating layer 5 covers the planarization layer 13 and also covers the peripheral portions of the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3.

The partition 6 has a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3. It should be noted that the cap layers CP1, CP2 and CP3 may be omitted.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer RL1. The resin layer RL1 is covered with a sealing layer 14. The sealing layer 14 is covered with a resin layer RL2.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The insulating layer 12 is formed of resin. The planarization layer 13 is formed of a positive photosensitive resin. The planarization layer 13 may be formed of a material which is different from that of the insulating layer 12 or may be formed of the same material as the insulating layer 12.

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode (reflecting electrode) formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

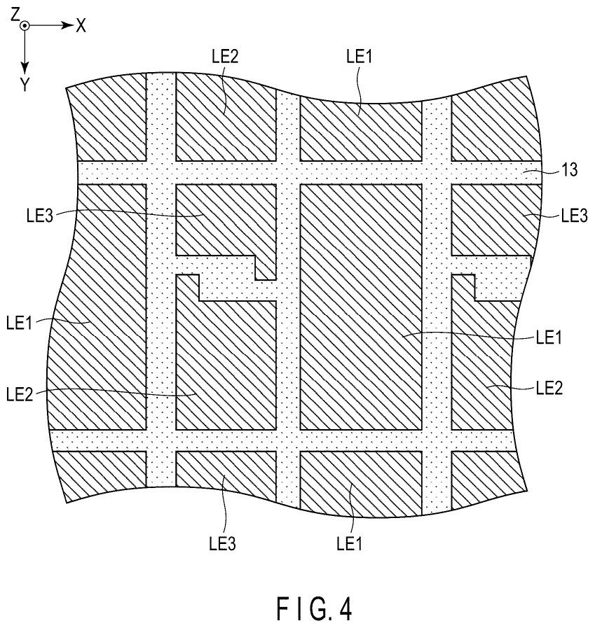

FIG. 4 is a plan view showing an example of the planarization layer 13.

The planarization layer 13 is formed into a grating shape in plan view. Each of the lower electrodes LE1, LE2 and LE3 is surrounded by the planarization layer 13. In other words, the side surfaces of the lower electrode LE1 are in contact with the planarization layer 13 over the whole circumference. Similarly, the side surfaces of the lower electrode LE2 are in contact with the planarization layer 13 over the whole circumference. The side surfaces of the lower electrode LE3 are also in contact with the planarization layer 13 over the whole circumference. In this structure, the step between the lower electrodes (LE1, LE2 and LE3) which are adjacent to each other is reduced by the planarization layer 13.

Since the step between the lower electrodes (LE1, LE2 and LE3) is reduced by the planarization layer 13 in this manner, the upper surface of the inorganic insulating layer 5 overlapping the planarization layer 13 and the lower electrodes LE1, LE2 and LE3 is planarized. This configuration prevents the generation of a crack in the inorganic insulating layer 5 because of the steps of the lower electrodes LE1, LE2 and LE3.

The crack of the inorganic insulating layer 5 could be the dispersion path of the moisture contained in the insulating layer 12. Thus, if the crack penetrates the inorganic insulating layer 5, the moisture contained in the insulating layer 12 may pass through the crack via the end portion of the lower electrode LE. In this case, the organic layer OR located on the inorganic insulating layer 5 is damaged by the moisture which passed through the crack, thereby causing the degradation of the luminescent performance.

As described above, the generation of a crack in the inorganic insulating layer 5 is prevented in the embodiment. Therefore, the dispersion path of the moisture contained in the insulating layer 12 is blocked. This configuration prevents the organic layer OR located on the inorganic insulating layer 5 from degrading because of moisture. In this way, the reduction in reliability can be prevented.

In addition, as the surface of the inorganic insulating layer 5 which is the base of the partition 6 is planarized, the partition 6 can be formed into a desired shape.

Further, compared to a case where the width of the lower portion 61 of the partition 6 is increased so as to cover a crack assuming that such a crack is generated in the inorganic insulating layer 5, an area which contributes to the display of each subpixel can be increased.

Moreover, compared to a case where, assuming that a crack is generated in the inorganic insulating layer 5, adjacent lower electrodes LE are provided so as to be close to each other, and the end portion of each lower electrode LE is located immediately under the lower portion 61, electric insulation between adjacent lower electrodes LE can be assured.

In addition, the planarization layer 13 formed of resin is covered with the inorganic insulating layer 5 and is not exposed from the inorganic insulating layer 5. Thus, the contact between the organic layer OR and the planarization layer 13 is avoided. This configuration can prevent the organic layer OR from degrading because of the moisture contained in the planarization layer 13.

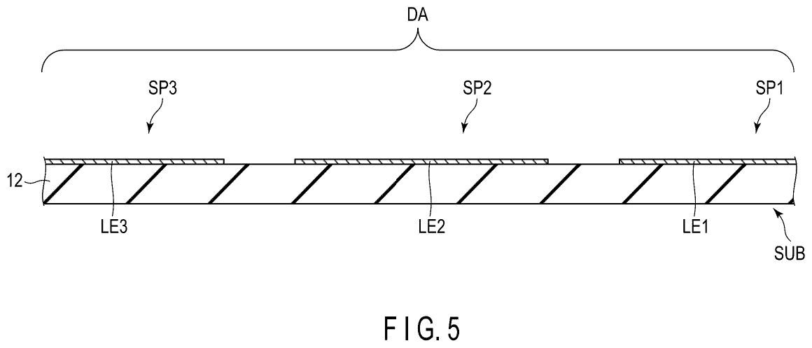

Now, this specification explains the manufacturing method of the display device DSP with reference to FIG. 5 to FIG. 14. In FIG. 5 to FIG. 14, the illustration of the lower side of the insulating layer 12 is omitted.

First, as shown in FIG. 5, a processing substrate SUB is prepared. The process of preparing the processing substrate SUB includes the process of forming the insulating layer 12, and the process of forming the lower electrode LE1 of subpixel SP1, the lower electrode LE2 of subpixel SP2 and the lower electrode LE3 of subpixel SP3 on the insulating layer 12. The process of forming the lower electrodes LE1, LE2 and LE3 includes the process of forming a transparent conductive layer, the process of forming a metal layer and the process of patterning these conductive layer and metal layer in a lump.

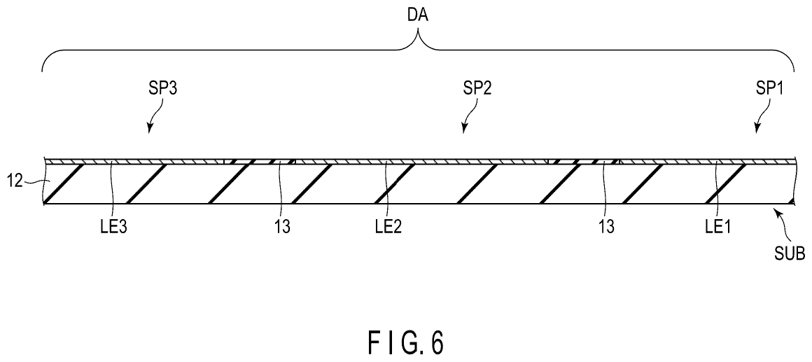

Subsequently, as shown in FIG. 6, the planarization layer 13 is formed on the insulating layer 12. The process of forming the planarization layer 13 includes, as described in detail later, the process of applying a photosensitive resin which covers the insulating layer 12 and the lower electrodes LE1, LE2 and LE3, and the process of patterning the photosensitive resin.

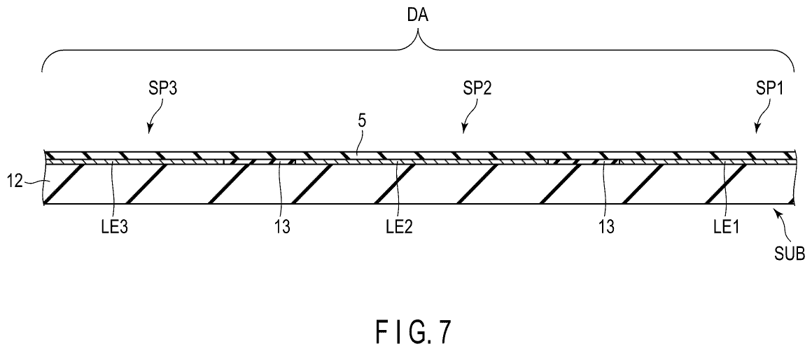

Subsequently, as shown in FIG. 7, the inorganic insulating layer 5 which covers the lower electrodes LE1, LE2 and LE3 and the planarization layer 13 is formed. For example, silicon oxynitride is deposited in the entire display area DA by a chemical vapor deposition (CVD) method.

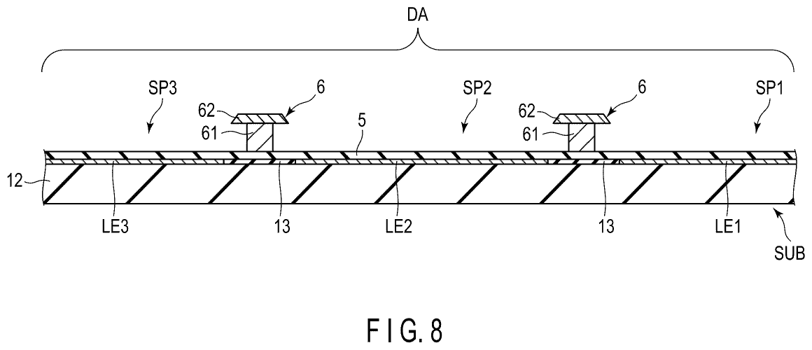

Subsequently, as shown in FIG. 8, the partition 6 is formed on the inorganic insulating layer 5. The process of forming the partition 6 includes the process of forming a metal layer on the inorganic insulating layer 5, the process of forming a thin film on the metal layer, the process of forming a resist corresponding to the shape of the partition 6 on the thin film, the process of etching the thin film and the metal layer in series using the resist as a mask and the process of removing the resist. The lower portion 61 located on the inorganic insulating layer 5 is formed by patterning the metal layer. The upper portion 62 located on the lower portion 61 and protruding from the side surfaces of the lower portion 61 is formed by patterning the thin film.

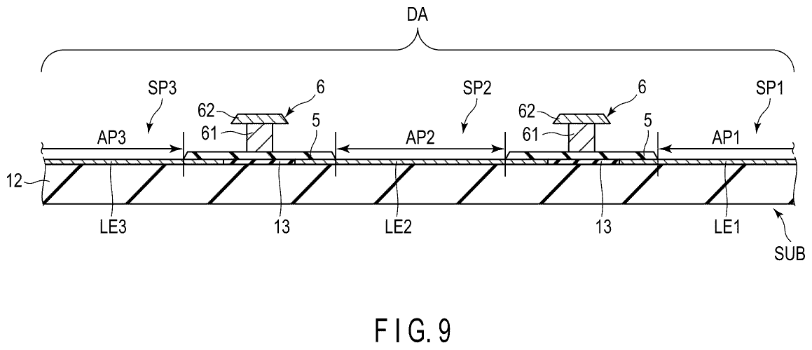

Subsequently, as shown in FIG. 9, the apertures AP1, AP2 and AP3 are formed in the inorganic insulating layer 5. The aperture AP1 overlaps the lower electrode LE1. The aperture AP2 overlaps the lower electrode LE2. The aperture AP3 overlaps the lower electrode LE3. The inorganic insulating layer 5 formed in this manner covers the planarization layer 13 and covers the peripheral portion of each of the lower electrodes LE1, LE2 and LE3.

In the example described above, the apertures AP1, AP2 and AP3 are formed after the formation of the partition 6. However, the configuration is not limited to this example. The partition 6 may be formed after the formation of the inorganic insulating layer 5 having the apertures AP1, AP2 and AP3.

Subsequently, the display element 201 is formed.

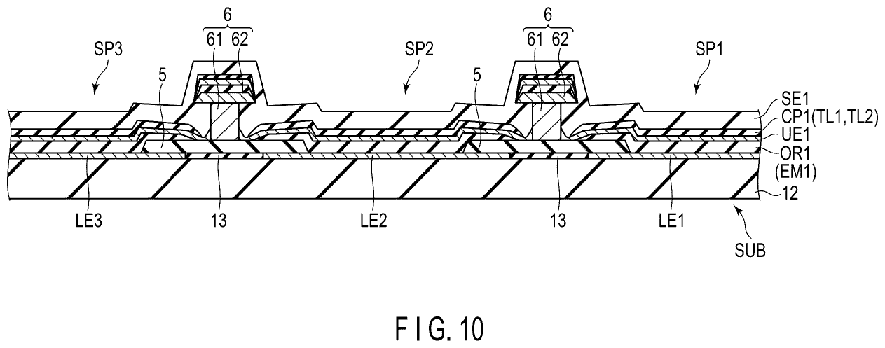

First, as shown in FIG. 10, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material for forming a first transparent layer TL1 and a low-refractive material for forming a second transparent layer TL2 in series on the upper electrode UE1 using the partition 6 as a mask.

These organic layer OR1, upper electrode UE1 and cap layer CP1 are successively formed while maintaining a vacuum environment.

Subsequently, the sealing layer SE1 is formed so as to continuously cover the cap layer CP1 and the partition 6 by a CVD method.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

The sealing layer SE1 covers the cap layer CP1 located immediately above the partition 6, covers the cap layer CP1 located immediately above the lower electrode LE1 and is in contact with the partition 6.

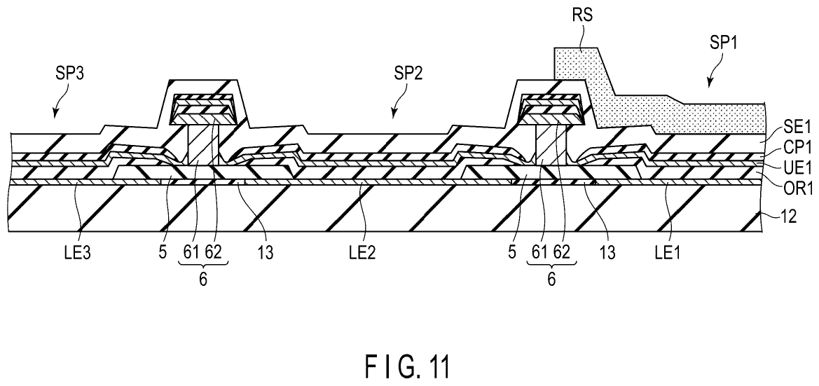

Subsequently, as shown in FIG. 11, a resist RS patterned into a predetermined shape is formed on the sealing layer SE1. The resist RS overlaps subpixel SP1 and part of the partition 6 around subpixel SP1.

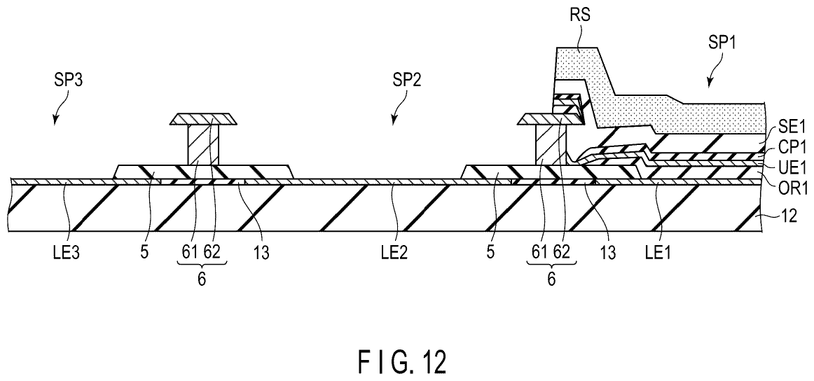

Subsequently, as shown in FIG. 12, the sealing layer SE1, cap layer CP1, upper electrode UE1 and organic layer OR1 exposed from the resist RS are removed in series by performing etching using the resist RS as a mask. In this manner, the lower electrode LE2 of subpixel SP2 and the lower electrode LE3 of subpixel SP3 are exposed.

Subsequently, the resist RS is removed. By this process, the display element 201 is formed in subpixel SP1.

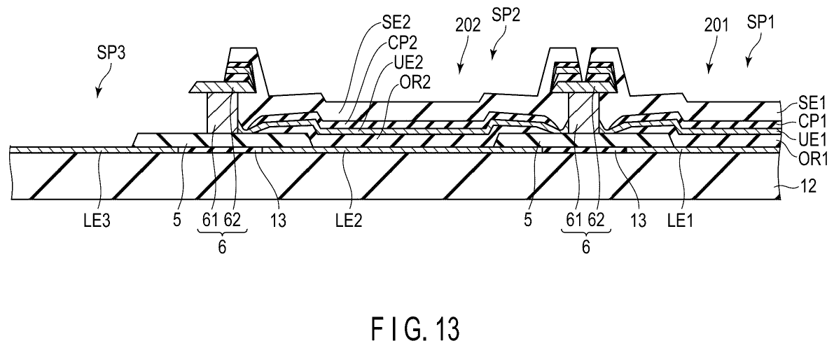

Subsequently, as shown in FIG. 13, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

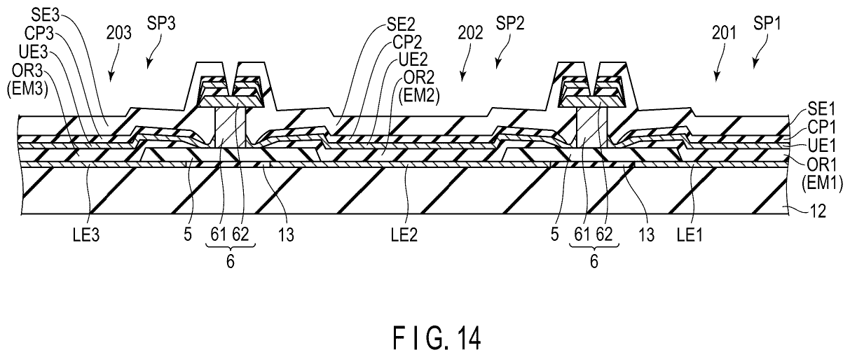

Subsequently, as shown in FIG. 14, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer RL1, sealing layer 14 and resin layer RL2 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains some methods for forming the planarization layer 13.

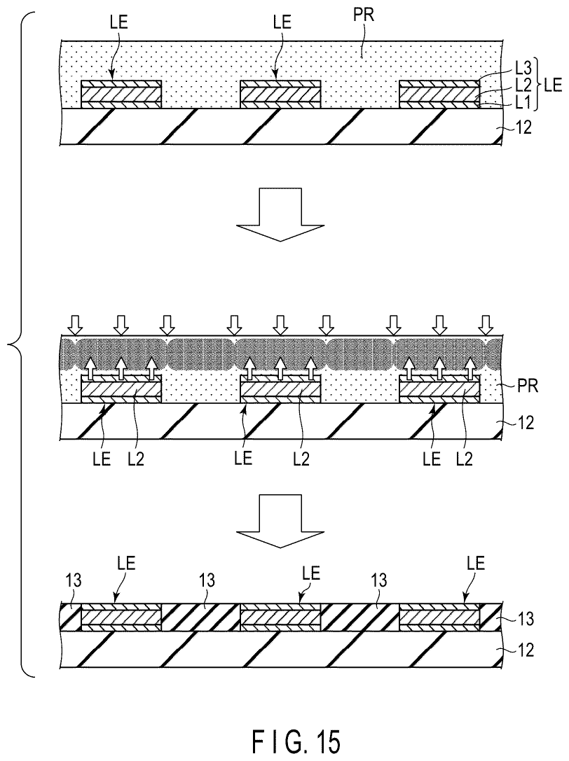

FIG. 15 is a diagram for explaining a method for forming the planarization layer 13.

First, as shown in the upper part, a positive photosensitive resin PR which covers the insulating layer 12 and a plurality of lower electrodes LE is applied. Here, each of the lower electrodes LE corresponds to one of the lower electrodes LE1, LE2 and LE3 shown in FIG. 3. Each of the lower electrodes LE is a multilayer body consisting of a first layer L1, a second layer L2 and a third layer L3. Both the first layer L1 and the third layer L3 is a transparent electrode. The second layer L2 is a metal electrode formed of silver etc. Thus, each of the lower electrodes LE has a metal electrode which could be a reflecting electrode between a pair of transparent electrodes.

Subsequently, as shown in the middle part, the whole surface of the photosensitive resin PR is exposed without using a mask. The area which overlaps each lower electrode LE in the photosensitive resin PR is exposed by the light emitted from the light source of an exposure device and is also exposed by the light reflected on the second layer L2 of the lower electrode LE. The area which does not overlap each lower electrode LE (or the area which overlaps the portion located between the adjacent lower electrodes LE) in the photosensitive resin PR is exposed by the light emitted from the light source. Thus, an exposure of the area which overlaps each lower electrode LE is greater than that of the area which does not overlap the lower electrodes LE. By this process, the surface layer of the photosensitive resin PR is exposed and is changed so as to exhibit solubility for a developer.

Subsequently, as shown in the lower part, the photosensitive resin PR is developed. By developing the photosensitive resin PR, the surface layer of the photosensitive resin PR is removed, and the upper surface of each lower electrode LE is exposed. The photosensitive resin PR remains between the lower electrodes LE.

Subsequently, the photosensitive resin PR is burned. By this process, moisture is eliminated from the photosensitive resin PR, and the planarization layer 13 is formed.

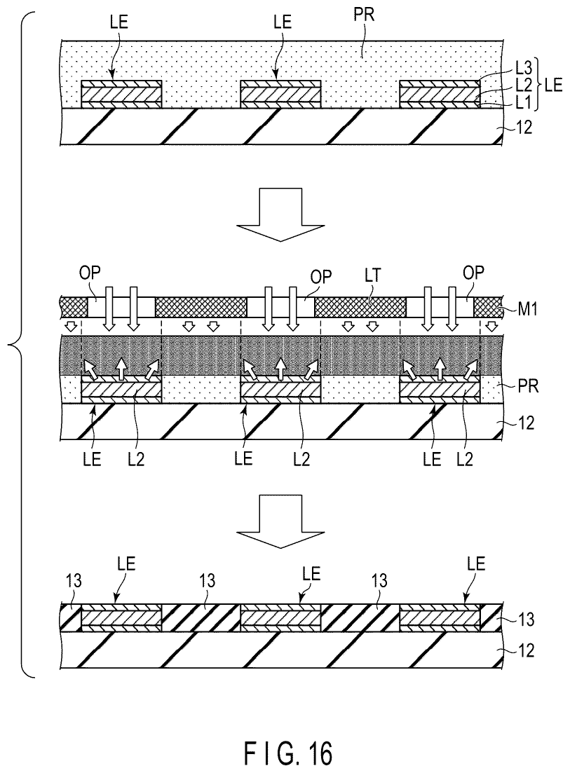

FIG. 16 is a diagram for explaining another method for forming the planarization layer 13. Explanations which overlap the matters explained with reference to FIG. 15 are omitted unless necessary.

First, a positive photosensitive resin PR which covers the insulating layer 12 and a plurality of lower electrodes LE is applied.

Subsequently, the photosensitive resin PR is exposed using a mask M1. The mask M1 has apertures OP and a low-transmissive portion LT having a transmittance which is lower than that of the apertures OP. Each aperture OP has a shape corresponding to each lower electrode LE. The low-transmissive portion LT has a shape corresponding to the area in which the planarization layer 13 should be formed (in other words, the area which does not overlap the lower electrodes LE). The low-transmissive portion LT has a width which is greater than the interval between the adjacent lower electrodes LE, and overlaps the end portions of the lower electrodes LE. When the photosensitive resin PR is exposed via this mask M1, an exposure condition on which the exposure of the area which overlaps each lower electrode LE is greater than that of the area which does not overlap the lower electrodes LE is realized.

The area which overlaps each lower electrode LE in the photosensitive resin PR is exposed by the light which passed through the aperture OP, and is also exposed by the light reflected on the second layer L2 of the lower electrode LE. The area which does not overlap the lower electrodes LE in the photosensitive resin PR is exposed by the light which passed through low-transmissive portions LT, and is also exposed by the diffused light reflected on the second layers L2 of the lower electrodes LE. Thus, the surface layer of the photosensitive resin PR is exposed and is changed so as to exhibit solubility for a developer.

Subsequently, the photosensitive resin PR is developed. Subsequently, the photosensitive resin PR is burned. By this process, the planarization layer 13 is formed.

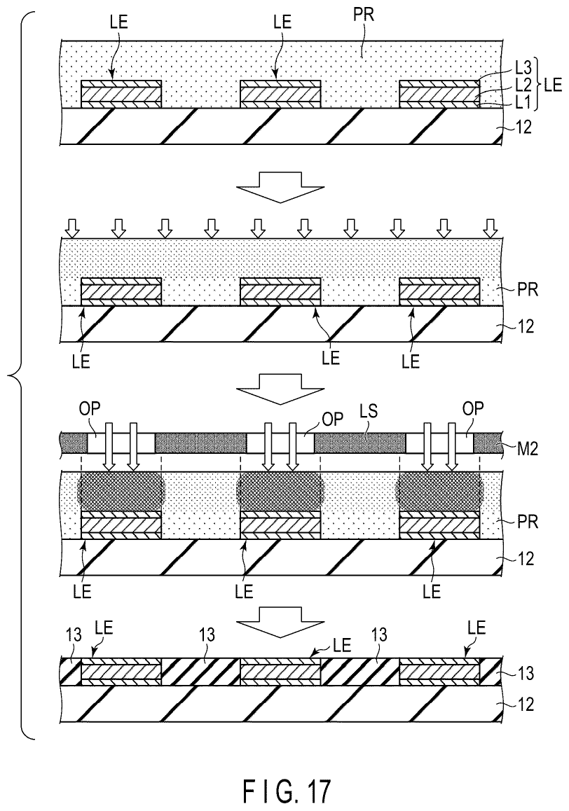

FIG. 17 is a diagram for explaining another method for forming the planarization layer 13. Explanations which overlap the matters explained with reference to FIG. 15 are omitted unless necessary.

First, a positive photosensitive resin PR which covers the insulating layer 12 and a plurality of lower electrodes LE is applied.

Subsequently, the whole surface of the photosensitive resin PR is exposed without using a mask.

Subsequently, the photosensitive resin PR is exposed using a mask M2. The mask M2 has apertures OP and a light-shielding portion LS. Each aperture OP has a shape corresponding to each lower electrode LE. The light-shielding portion LS has a shape corresponding to the area in which the planarization layer 13 should be formed (in other words, the area which does not overlap the lower electrodes LE). The light-shielding portion LS has a width which is greater than the interval between the adjacent lower electrodes LE, and overlaps the end portions of the lower electrodes LE.

The area which overlaps each lower electrode LE in the photosensitive resin PR is exposed in the preceding whole-surface exposure process and is also exposed by the light which passed through the aperture OP by the exposure process using the mask M2. While the area which does not overlap the lower electrodes LE in the photosensitive resin PR is exposed in the preceding whole-surface exposure process, this area is shielded from light by the light-shielding portion LS in the exposure process using the mask M2. By forming this difference in the exposure, the photosensitive resin PR located in the area overlapping each lower electrode LE is exposed so as to be assuredly removed, and the photosensitive resin PR located in the area which does not overlap the lower electrodes LE is exposed such that the surface layer can be removed and the bottom portion remains.

Subsequently, the photosensitive resin PR is developed. Subsequently, the photosensitive resin PR is burned. By this process, the planarization layer 13 is formed.

Now, this specification explains cross-sectional shapes which could be formed in the planarization layer 13.

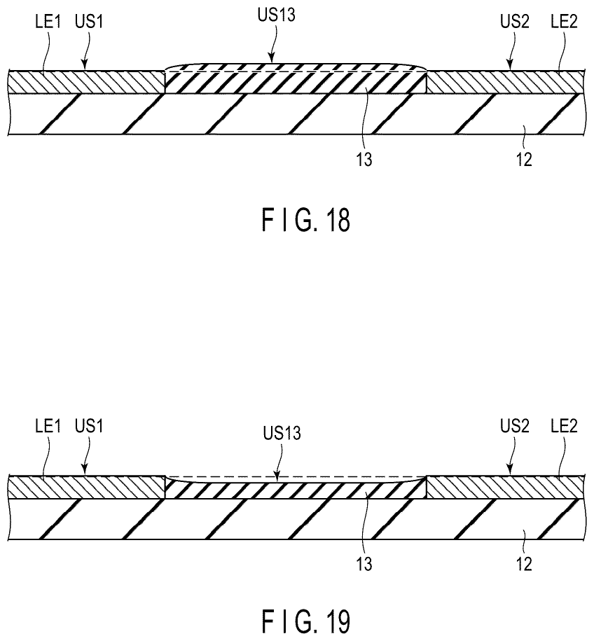

FIG. 18 is a diagram showing an example of the cross-sectional shape of the planarization layer 13.

The upper surface US13 of the planarization layer 13 protrudes relative to the upper surface US1 of the lower electrode LE1 and the upper surface US2 of the lower electrode UE2. In the example shown in the figure, the entire upper surface US13 protrudes relative to the upper surface US1 etc., and forms a convex surface. Part of the upper surface US13 could protrude relative to the upper surface US1 etc. Although the illustration of the lower electrode LE3 is omitted in FIG. 18, at least part of the upper surface US13 protrudes relative to the upper surface of each of the lower electrodes LE1, LE2 and LE3. For example, the thickness of the planarization layer 13 is the greatest at a middle point which is substantially equally distant from the adjacent lower electrodes LE.

FIG. 19 is a diagram showing another example of the cross-sectional shape of the planarization layer 13.

The upper surface US13 of the planarization layer 13 is concave relative to the upper surface US1 of the lower electrode LE1 and the upper surface US2 of the lower electrode LE2. In the example shown in the figure, the entire upper surface US13 is concave relative to the upper surface US1 etc., and forms a concave surface. Part of the upper surface US13 could be concave relative to the upper surface US1 etc. Although the illustration of the lower electrode LE3 is omitted in FIG. 19, at least part of the upper surface US13 is concave relative to the upper surface of each of the lower electrodes LE1, LE2 and LE3. For example, the thickness of the planarization layer 13 is the least at a middle point which is substantially equally distant from the adjacent lower electrodes LE.

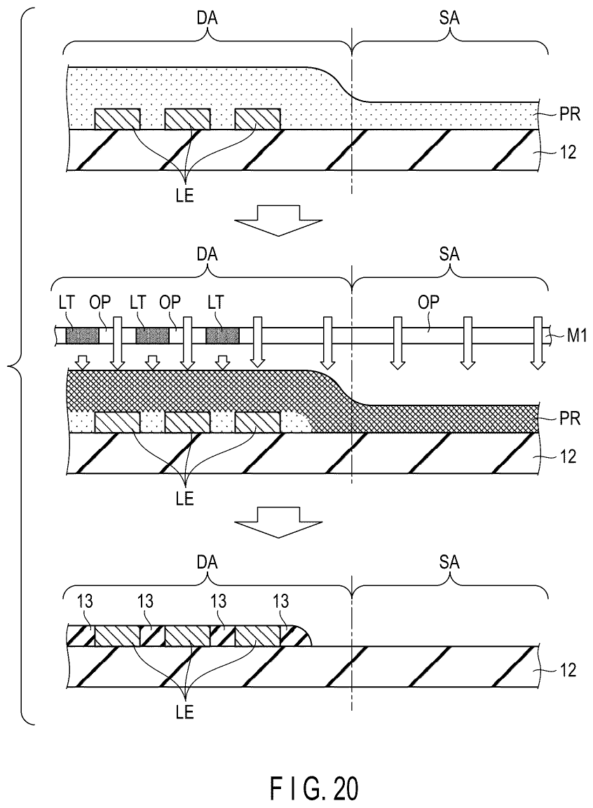

FIG. 20 is a diagram for explaining the process of selectively forming the planarization layer 13 in the display area DA.

First, as shown in the upper part, a positive photosensitive resin PR which covers the insulating layer 12 and a plurality of lower electrodes LE is applied. At this time, the photosensitive resin PR is applied to the surrounding area SA in addition to the display area DA.

Subsequently, as shown in the middle part, the photosensitive resin PR is exposed using a mask M1. The mask M1 has apertures OP and a low-transmissive portion LT having a transmittance which is lower than that of the apertures OP. The apertures OP have a shape corresponding to the lower electrodes LE and the surrounding area SA. The low-transmissive portion LT has a shape corresponding to the area in which the planarization layer 13 should be formed (in other words, the area which does not overlap the lower electrodes LE). When the photosensitive resin PR is exposed via this mask M1, an exposure condition on which the exposure of the area which overlaps each lower electrode LE and the surrounding area SA is greater than that of the area which does not overlap the lower electrodes LE in the display area DA is realized.

The areas which overlap the lower electrodes LE and the surrounding area SA in the photosensitive resin PR are exposed by the light which passed thorough the apertures OP. The area which does not overlap the lower electrodes LE in the display area DA in the photosensitive resin PR is exposed by the light which passed through the low-transmissive portion LT. Thus, the surface layer of the photosensitive resin PR located in the display area DA is exposed, and further, the entire photosensitive resin PR located in the surrounding area SA is exposed. The exposed area of the photosensitive resin PR is changed so as to exhibit solubility for a developer.

Subsequently, as shown in the lower part, the photosensitive resin PR is developed. Subsequently, the photosensitive resin PR is burned. By this process, the planarization layer 13 is formed. In the surrounding area SA, the photosensitive resin PR is removed. By this process, the terminals TE etc., shown in FIG. 1 are exposed from the planarization layer 13 in the surrounding area SA.

In FIG. 20, this specification explains the case where the photosensitive resin PR of the surrounding area SA is removed using the mask M1 shown in FIG. 16. However, the photosensitive resin PR of the surrounding area SA may be removed using the mask M2 shown in FIG. 17. Alternatively, the photosensitive resin PR of the surrounding area SA may be removed by applying the whole-surface exposure process shown in FIG. 15.

As explained above, the embodiment can provide a display device and a manufacturing method of a display device such that the reduction in reliability can be prevented.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
an organic insulating layer provided above the substrate;
a lower electrode provided on the organic insulating layer;
a planarization layer which is provided on the organic insulating layer and is in contact with a side surface of the lower electrode;
an inorganic insulating layer which covers the planarization layer and covers a peripheral portion of the lower electrode;
a partition having a lower portion which is provided on the inorganic insulating layer and is formed of a conductive material and an upper portion which is provided on the lower portion and protrudes from a side surface of the lower portion;
an organic layer surrounded by the partition, provided on the lower electrode and including a light emitting layer; and
an upper electrode which is surrounded by the partition, is provided on the organic layer and is in contact with the lower portion of the partition.

2. The display device of claim 1, wherein
the planarization layer is formed into a grating shape in plan view.

3. The display device of claim 1, wherein
at least part of an upper surface of the planarization layer protrudes relative to an upper surface of the lower electrode.

4. The display device of claim 1, wherein
at least part of an upper surface of the planarization layer is concave relative to an upper surface of the lower electrode.

5. The display device of claim 1, wherein
the planarization layer is formed of a positive photosensitive resin.

6. The display device of claim 1, further comprising:
a cap layer provided on the upper electrode; and
a sealing layer provided on the cap layer and formed of an inorganic insulating material, wherein
the sealing layer covers the cap layer immediately above the lower electrode and is in contact with the partition.

7. A manufacturing method of a display device, comprising:
forming an organic insulating layer above a substrate;
forming a lower electrode on the organic insulating layer;
applying a positive photosensitive resin which covers the organic insulating layer and the lower electrode;
forming a planarization layer which is in contact with a side surface of the lower electrode by patterning the photosensitive resin;
forming an inorganic insulating layer which covers the planarization layer and covers a peripheral portion of the lower electrode;
forming a partition having a lower portion which is located on the inorganic insulating layer and is formed of a conductive material and an upper portion which is located on the lower portion and protrudes from a side surface of the lower portion;
forming an organic layer which is located on the lower electrode and includes a light emitting layer by vapor deposition using the partition as a mask; and
forming an upper electrode which is located on the organic layer and is in contact with the lower portion of the partition by vapor deposition using the partition as a mask.

8. The manufacturing method of claim 7, wherein
the process of patterning the photosensitive resin includes:
exposing a whole surface of the photosensitive resin without using a mask;
developing the photosensitive resin; and
burning the photosensitive resin.

9. The manufacturing method of claim 7, wherein
the process of patterning the photosensitive resin includes:
exposing the photosensitive resin on an exposure condition that an exposure of an area which overlaps the lower electrode is greater than an exposure of an area which does not overlap the lower electrode;
developing the photosensitive resin; and
burning the photosensitive resin.

10. The manufacturing method of claim 7, wherein
the process of patterning the photosensitive resin includes:
exposing a whole surface of the photosensitive resin without using a mask;
exposing the photosensitive resin using a mask which has an aperture in an area overlapping the lower electrode and shields an area which does not overlap the lower electrode from light;
developing the photosensitive resin; and
burning the photosensitive resin.

11. The manufacturing method of claim 7, further comprising, after forming the upper electrode,
forming a cap layer on the upper electrode, and
forming a sealing layer on the cap layer by using an inorganic insulating material, wherein
the sealing layer covers the cap layer immediately above the lower electrode and is in contact with the partition.

12. The manufacturing method of claim 11, further comprising, after forming the sealing layer,
forming a patterned resist on the sealing layer, and
removing the sealing layer, the cap layer, the upper electrode and the organic layer exposed from the resist in series by etching.
